(19) United States
(12) Patent Application Publication
(10) Pub. No.: US 2014/0154832 A1
(43) Pub. Date: Jun. 5, 2014

(54) PLASMA PROCESSING APPARATUS AND PLASMA PROCESSING METHOD

(71) Applicants: Shogo Okita, Hyogo (JP); Syouzou Watanabe, Osaka (JP)

(72) Inventors: Shogo Okita, Hyogo (JP); Syouzou Watanabe, Osaka (JP)

(21) Appl. No.: 14/233,276

(22) PCT Filed: Jun. 29, 2012
(86) PCT No.: PCT/JP2012/004223

§ 371 Date: Jan. 16, 2014

(30) Foreign Application Priority Data
Jul. 26, 2011 (JP) 2011-163228

(51) Int. Cl. H01L 31/18; H01L 21/67

(52) U.S. Cl. CPC H01L 31/18; H01L 21/67069
USPC 438/71; 156/345.51; 156/345.53

(57) ABSTRACT

A dry etching apparatus includes a tray for conveying substrates. The tray has substrate housing holes as through holes each capable of housing the three substrates. The substrates are supported by a substrate support section protruding from a hole wall of each of the substrate housing holes. A stage is provided in a chamber in which plasma is generated. The stage includes substrate installation sections to be inserted from a lower surface side of the tray to the substrate housing holes so that lower surfaces of the plurality of the substrates transferred from the substrate support section are installed on substrate installation surfaces that are their upper end surfaces. High shape controllability and favorable productivity for the angular substrate can be implemented while preventing increased in size of the apparatus.

### TECHNICAL FIELD

The present invention relates to a plasma processing apparatus and a plasma processing method.

### BACKGROUND ART

As for solar batteries, the optical confinement technique has been developed in order to improve conversion efficiency. According to the optical confinement techniques, a solar battery surface is roughened, a texture is formed on the solar battery surface, or a concavo-convex shape is formed on a substrate itself. As for the roughening, roughening by wet etching is disclosed in patent document 1, and roughening by dry etching (RIE etching) is disclosed in patent document 2, and it is known that isotropic plasma is used in the process. In addition, as for the formation of the texture, formation of a texture by wet etching is disclosed in each of patent documents 3 and 4, and formation of a texture by dry etching (RIE etching) is disclosed in patent document 5. In addition, as for the formation of the concavo-convex shape in the substrate itself, formation of a V groove in a substrate surface by wet etching is disclosed in patent document 6, and formation of a V groove by mechanical etching is disclosed in patent document 7.

Meanwhile, there is a commonly-known dry etching apparatus which performs a batch process by use of a tray capable of conveying a plurality of substrates. For example, patent document 8 discloses a plasma processing apparatus in which substrates are housed and conveyed in a plurality of substrate housing holes each having a bottom and provided in a tray. In addition, patent document 9 discloses a plasma processing apparatus in which substrates are housed and conveyed in substrate housing holes each penetrating in a thickness direction and provided in a tray.

### CITATION LIST

### Patent Documents

Patent Document 1: Japanese Patent No. 3301663

Patent Document 2: JP 2003-197940 A

Patent Document 3: Japanese Patent No. 2997366

Patent Document 4: Japanese Patent No. 2866982

Patent Document 5: JP 2010-21196 A

Patent Document 6: Japanese Patent No. 2989055

Patent Document 7: Japanese Patent No. 2749228

Patent Document 8: JP 2006-066417 A

Patent Document 9: Japanese Patent No. 436105

### SUMMARY OF THE INVENTION

### Problems to be Solved by the Invention

Whenever any one of the above-described optical confinement techniques is employed, it is necessary to process front and back surfaces of the solar battery and the substrate to form various shapes. In such process, high production efficiency is required, and also high shape controllability is required to efficiently implement the optical confinement.

The wet etching is generally performed by the batch process, and the isotropic plasma process is also generally performed by the batch process using a barrel type plasma processing apparatus. In those butch processes, it is difficult to implement the high shape controllability. Meanwhile, when the wet etching and the isotropic plasma process are executed by a single-wafer process, in order to ensure the shape controllability, production efficiency is considerably low, so that production cost is considerably increased.

Anisotropic etching by the RIE etching can provide the high shape controllability, but when it is executed by the single-wafer process, its production efficiency is considerably low.

As for the plasma device disclosed in the patent document 8 having the configuration in which the substrates are housed in the plurality of the holes each having the bottom and provided in the conveyable tray, the batch process can be performed as described above. However, each substrate housed in the hole having the bottom is cooled with the tray interposed, so that the substrate cannot be effectively cooled. As a result, high bias power cannot be inputted, and temperature controllability is not favorable, so that the productivity and the shape controllability are both not favorable. As for the plasma processing apparatus in the patent document 9 having the configuration in which the substrates are housed in the holes penetrating in the thickness direction and provided in the conveyable tray, the batch process can be performed. Since each substrate can be directly cooled without the tray, the substrate can be effectively cooled and high bias power can be inputted.

The substrate of the solar battery is rectangular or angular in shape in general. However, in the plasma processing apparatus disclosed in the patent document 9, the batch process is intended to be performed mainly for a plurality of round-shaped substrates, so that enough consideration is not made to prevent an increase in size of the tray and therefore an increase in size of the device when the angular substrate is used. Especially, the substrate of the current solar battery is 125 mm square in general, but in a case where the nine angular substrates each having this size are arranged by 3×3 in the tray in the patent document 9, respective circumstances of the nine angular substrates need to be surrounded by the tray, so that the tray is increased in size. As the tray is increased in size, the plasma processing apparatus is increased in size as a whole.

As described above, regarding the conventional plasma process, it is not possible to optimize both shape controllability and productivity while the device is prevented from being increased in size, with respect to the relatively large angular substrate like the substrate of the solar battery.

It is an object of the present invention to provide a plasma processing apparatus and a plasma processing method capable of realizing both high shape controllability and favorable productivity while the device is prevented from being increased in size.

### MEANS FOR SOLVING THE PROBLEMS

A first aspect of the present invention provides a plasma processing apparatus comprising, a conveyable tray comprising at least one substrate housing hole provided so as to penetrate in a thickness direction to house a plurality of substrates, and a substrate support section protruding from a hole wall of the substrate housing hole to support an outer edge section of a lower surface of each of the plurality of the substrates housed in the substrate housing hole, a plasma generation source for generating plasma in a chamber in which the tray is to be conveyed, and a stage arranged in the chamber and comprising a tray support section for supporting the tray, and a substrate installation section to be inserted from a lower surface side of the tray to the substrate housing hole, to install lower surfaces of the plurality of the substrates transferred from the substrate support section on a substrate installation surface which is an upper end surface of the substrate installation section.

The lower surface of the substrate is directly installed on the substrate installation surface of the substrate installation section without having the tray between them. More specifically, the substrate installation section is inserted from the lower surface side of the tray into the substrate housing hole, and the substrate is installed on the substrate installation surface which is an upper end surface of the substrate installation section. The substrate directly installed on the substrate installation surface without having the tray between them can be cooled with high efficiency, and its temperature can be controlled with high precision. As a result, the high shape controllability can be realized.

In addition, since the plurality of the substrates are housed in at least one substrate housing hole in the tray, the batch process can be performed for the plurality of the substrates, so that the favorable productivity can be realized.

Furthermore, not one but the plurality of the substrates are housed in each substrate housing hole in the tray, and the plurality of the substrates transferred from the substrate support section of the substrate housing hole are installed on the substrate installation surface of the substrate installation section in the stage. Since the plurality of the substrates are housed in the substrate housing hole in the tray, the tray can be prevented from being increased in size, and therefore the plasma processing apparatus can be prevented from being increased in size. In addition, since the plurality of the substrates are arranged on the substrate installation surface of the one substrate installation section, the structure of the stage can be simplified.

As described above, according to the plasma processing apparatus in the present invention, the high shape controllability and the favorable productivity can be both realized while the device is prevented from being increased in size.

Specifically, the tray houses the plurality of the substrates so that abutment sections of the adjacent substrates abut on each other.

For example, the substrate is an angular substrate, and the abutment section is one side of the angular substrate.

Preferably, the plasma processing apparatus further includes a deflection prevention member provided in the tray so as to cross the substrate housing hole in planar view to support a lower surface side of the substrate, and a housing groove provided in the substrate support section of the stage to receive the deflection prevention member when the tray is supported by the tray support section.

Since the deflection prevention member is provided in addition to the substrate support section, the housed substrate is prevented from being deflected downward due to its own weight even when the plurality of the relatively large substrates are housed in each substrate housing hole. On the other hand, the deflection prevention member does not prevent the substrate from being installed on the substrate installation surface because it is housed in the housing groove of the substrate installation section in the stage.

Preferably, the plasma processing apparatus further includes an electrostatic chucking electrode for electrostatically chucking the substrate onto the substrate installation surface, and a drive power supply for supplying a drive voltage to the electrostatic chucking electrode.

Moreover, preferably, the plasma processing apparatus further includes a cooling mechanism for cooling the stage.

More preferably, the plasma processing apparatus further includes a heat-transfer gas supply mechanism for supplying a heat-transfer gas between the substrate installation surface and the substrate.

When a DC voltage is applied from the drive power supply to the electrostatic chucking electrode, the substrate is held on the substrate installation surface with a high degree of adhesion. As a result, heat conduction by the heat-transfer gas is favorably provided between the substrate installation surface serving as one section of the stage which is cooled by the cooling mechanism, and the substrate, so that the substrate can be cooled down with high cooling efficiency, and the substrate temperature can be controlled with high precision.

A second aspect of the present invention provides a plasma processing method including providing a tray having at least one substrate housing hole provided so as to penetrate in a thickness direction to house a plurality of substrates, and a substrate support section protruding from a hole wall of the substrate housing hole, housing the plurality of the substrates in the substrate housing hole in the tray so that an outer edge section of a lower surface of each of the substrates is put on the substrate support section, lowering the tray toward a stage in a chamber so that the tray is supported with a tray support section of the stage while a substrate installation section is inserted from a lower surface side of the tray into the substrate housing hole, thereby installing the lower surfaces of the plurality of the substrates housed in the substrate housing hole, on a substrate installation surface which is an upper end surface of the substrate installation section, and generating plasma in the chamber.

### EFFECT OF THE INVENTION

According to the plasma processing apparatus and the plasma processing method in the present invention, not the one but the plurality of the substrates are housed in the substrate housing hole in the tray, and the plurality of the substrates transferred from the substrate support section of the substrate housing hole are installed on the substrate installation surface of the substrate installation section in the stage, so that the high shape controllability and the favorable productivity can be both realized while the device is prevented from being increased in size.

### BRIEF DESCRIPTION OF THE DRAWINGS

FIG. 1 is a schematic view of a dry etching apparatus according to an embodiment of the present invention;

FIG. 2 is a perspective view of a stage and a tray;

FIG. 3 is an exploded perspective view of the tray;

FIG. 4 is a cross-sectional view of the stage showing one example of arrangement of an electrostatic chucking electrode;

FIG. 5 is a perspective view of substrates;

FIG. 6A is a partial cross-sectional view of a state before the tray is arranged on the stage in cross-section perpendicular to an X axis in FIGS. 2 and 3;

FIG. 6B is a partial cross-sectional view of a state after the tray has been arranged on the stage in cross-section perpendicular to the X axis in FIGS. 2 and 3;

FIG. 7A is a partial cross-sectional view of a state before the tray is arranged on the stage in cross-section perpendicular to a Y axis in FIGS. 2 and 3; and

FIG. 7B is a partial cross-sectional view of a state after the tray has been arranged on the stage in cross-section perpendicular to the Y axis in FIGS. 2 and 3.

### DESCRIPTION OF EMBODIMENTS

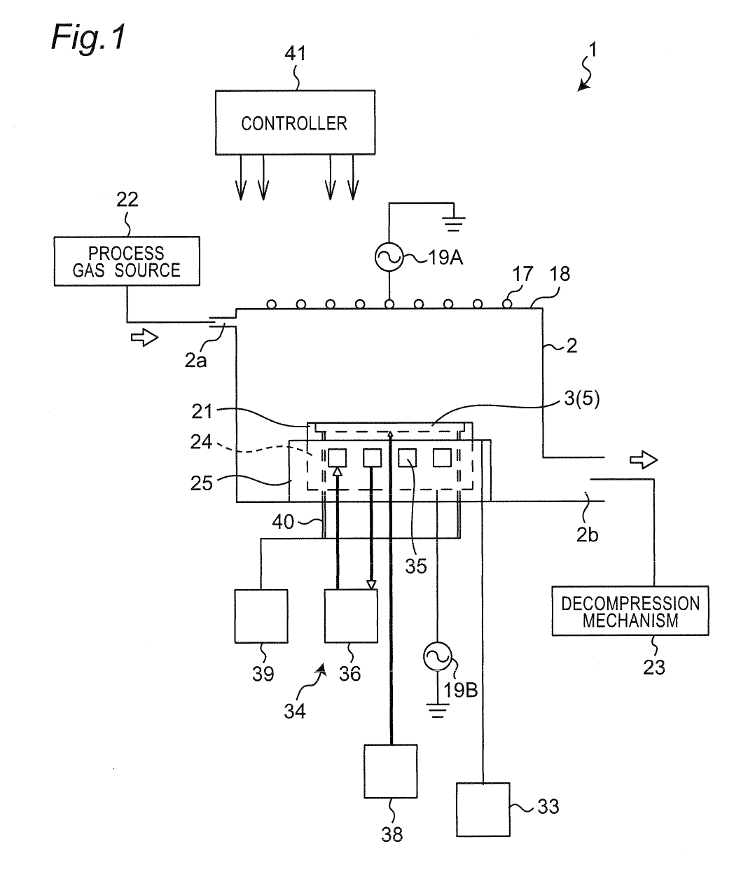

FIGS. 1 to 4 show a dry etching apparatus 1 serving as one example of a plasma processing apparatus according to an embodiment of the present invention. The dry etching apparatus 1 includes a tray 3 which can be conveyed to and from a chamber (chamber) 2 in which pressure can be reduced to generate plasma, through an inlet and an outlet (not shown).

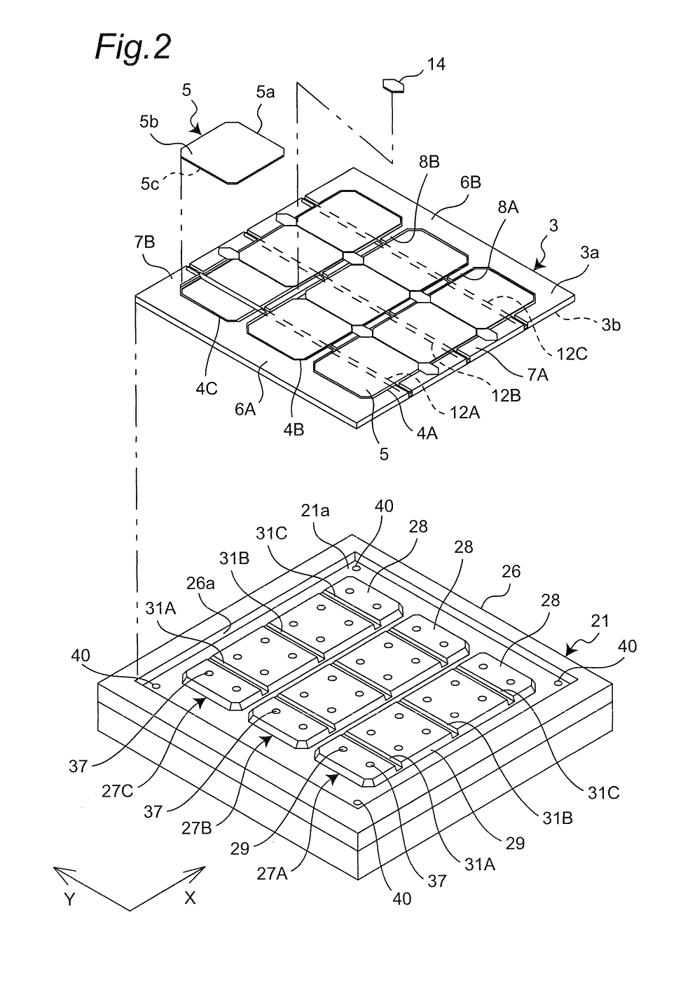

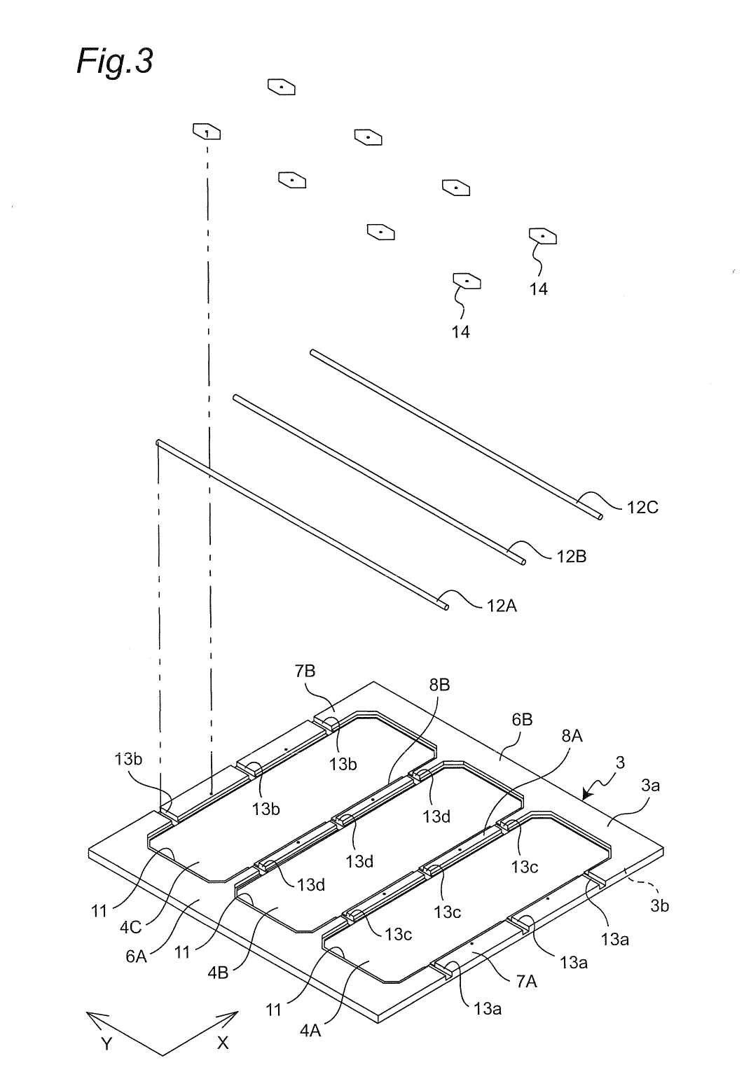

Referring to FIGS. 2 and 3, the tray 3 has a plate-like shape having a rectangular outline as a whole and a constant thickness. The tray 3 has three substrate housing holes 4A, 4B, and 4C each having a roughly rectangular shape in planar view and penetrating from an upper surface 3a to a lower surface 3b in a thickness direction. These substrate housing holes 4A to 4C are the same in shape and dimension. In each of the substrate housing holes 4A to 4C, not one but three substrates 5 are housed.

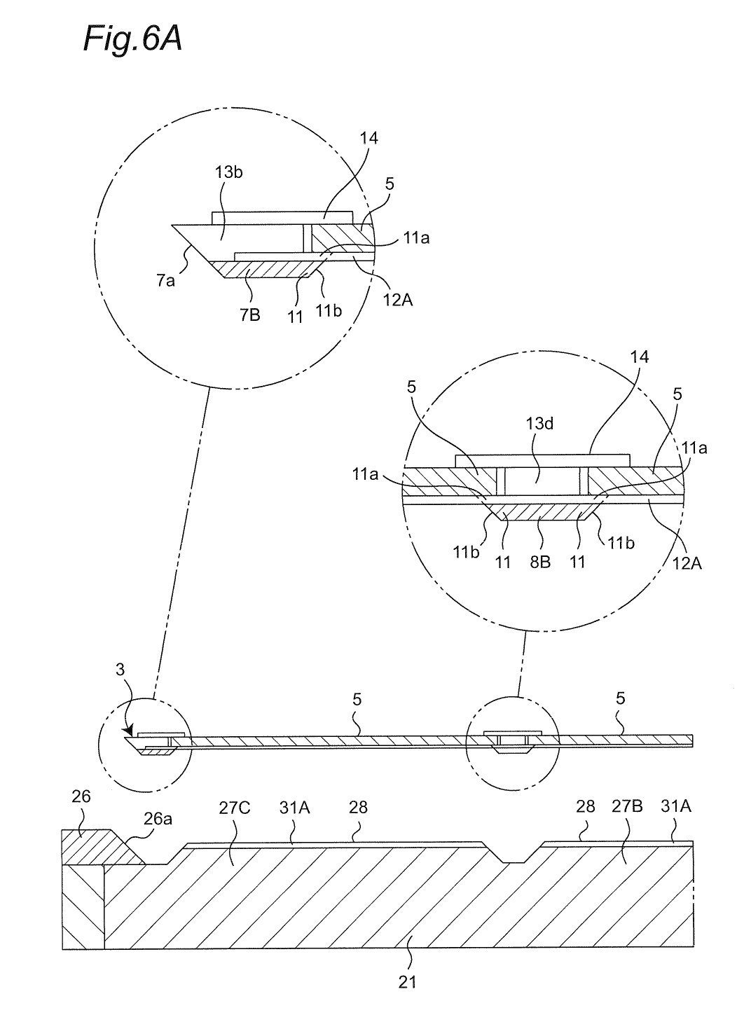

Referring to FIG. 5 together, the substrate 5 in this embodiment is an angular substrate in which its four corners are chamfered, and has four linear sides 5a in planar view. A size of the substrate 5 is not limited in particular, but it may be 125 mm square for use in a solar battery. Since the substrate 5 serving as the angular substrate is the angular substrate, the two adjacent substrates 5 can be closely arranged in substantially the same plane when their sides 5 abut on each other.

The three substrate housing holes 4A to 4C in the tray 3 are arranged in a row (a Y-axis direction in FIGS. 2 and 3) so that their long sides are opposed to each other in planar view. The tray 3 has outer frames 6A and 6B for defining both short sides of each of the three substrate housing holes 4A to 4C, and outer frames 7A and 7B for defining long sides of the two outer substrate housing holes 4A and 4C. In addition, the tray 3 has middle frames 8A and 8B positioned between the substrate housing holes 4A and 4B, and between the substrate housing holes 4B and 4C, respectively.

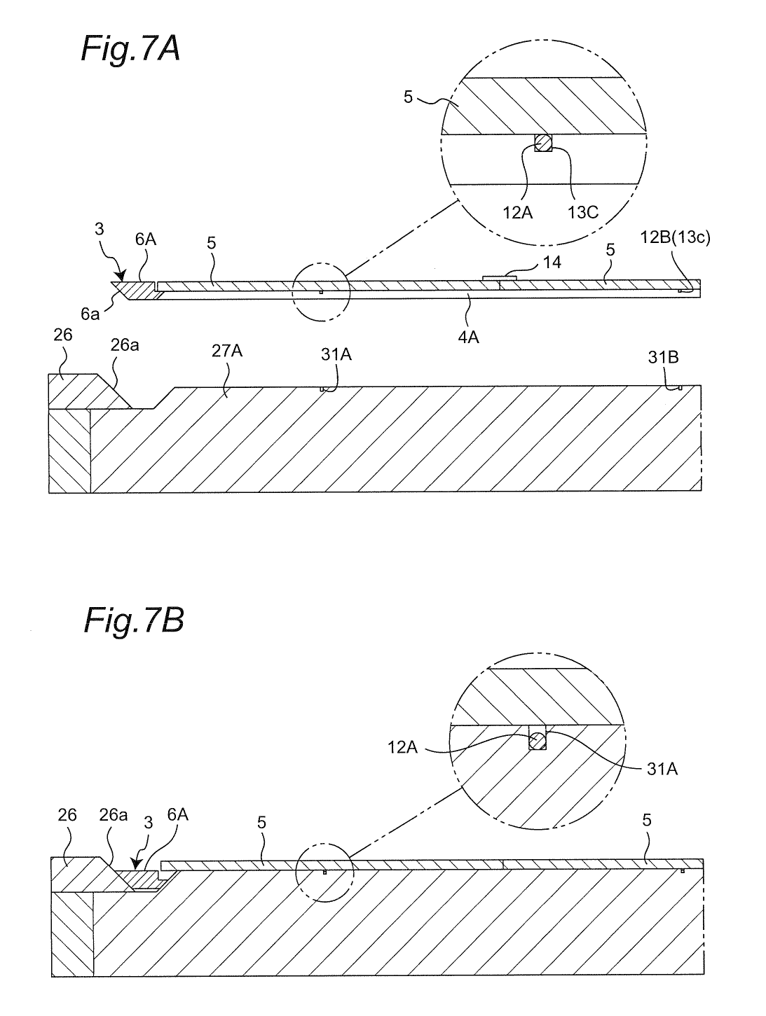

A substrate support section 11 is provided around a whole circumference of a hole wall of each of the substrate housing holes 4A to 4C. Referring to FIG. 7A together, the substrate support section 11 has an upper surface serving as a substantially horizontal support surface 11a and a lower surface serving as an inclined surface 11b. This inclined surface 11b is inclined so that the dimension of each of the substrate housing holes 4A to 4C is gradually reduced from the lower surface 3b toward the upper surface 3a of the tray 3. In addition, inclined surfaces 6a and 7a which are inclined so as to be widened outward from the lower surface 3b toward the upper surface 3a are provided on lower surface sides of the outer frames 6A to 7B of the tray 3.

In each of the substrate housing holes 4A to 4C, the three substrates 5 are housed. That is, according to this embodiment, the nine substrates 5 are arranged in the tray 3 in a matrix shape of 3×3. An outer edge section of a lower surface 5b of the substrate 5 is supported by the support surface 11a of the substrate support section 11. As described above, the substrate housing holes 4A to 4C are formed so as to penetrate in the thickness direction. Therefore, upper surfaces 5c of the substrates 5 housed in the substrate housing holes 4A to 4C are exposed when viewed from the upper surface 3a side of the tray 3, and the lower surfaces 5b of the housed substrates 5 are also exposed when viewed from the lower surface 3b side of the tray 3.

The three substrates 5 housed in each of the substrate housing holes 4A to 4C are arranged in such a manner that their sides (abutment sections) 5a abut on each other and arranged to be closely adjacent to each other. That is, the three substrates 5 housed in each of the substrate housing holes 4A to 4C are arranged in a row (an X-axis direction in FIG. 2) in planar view, and arranged such that the one pair of sides 5a opposed to each other in the center substrate 5 (one pair of sides opposed to the X-axis direction in FIG. 2) abuts on the sides 5a of the other substrates 5.

As for the three substrates 5 housed in each of the substrate housing holes 4A to 4C, their outer edge sections of the lower surfaces 5b are supported by the support surface 11a of the substrate support section 11 as described above, and in addition, their centers are supported by deflection prevention rods (deflection prevention members) 12A, 12B, and 12C. According to this embodiment, one of the rods 12A to 12C is provided with respect to each substrate 5. Each of the rods 12A to 12C in this embodiment is a substantially straight rod having rigidity so as to be able to support the substrate 5 and circular in cross-section. Each of the rods 12A to 12C is provided so as to cross the three substrate housing holes 4A to 4C. The upper surface 3a of the tray 3 has three groups of retention grooves in which one group includes linear retention grooves 13a and 13b provided in the outer frame 7A and 7B, and retention grooves 13c and 13d provided in the middle frames 8A and 8B. The retention grooves 13a to 13d in the one group are linearly arranged in a direction (the Y-axis direction in FIG. 2) so as to cross the three substrate housing holes 4A to 4C in planar view. One of the rods 12A to 12C is housed in the one group of the retention grooves 13a to 13d. A depth of each of the retention grooves 13a to 13d is set such that each of the rods 12A to 12C is substantially at the same level as the support surface 11a of the substrate support section 11, or slightly lower than the support surface 11a. The rods 12A to 12C may be fixed in the retention grooves 13a to 13d, or may be movable therein.

As for the center substrate 5 among the three substrates 5 housed in each of the substrate housing holes 4A to 4C, the opposed pair of sides 5a (pair of sides 5a opposed in the Y-axis direction in FIG. 2) is supported from the lower surface 5b by the support surface 11a of the substrate support section 11. In addition, as for the substrate 5 on each side among the three substrates 5 housed in each of the substrate housing holes 4A to 4C, the opposed pair of sides 5a (pair of sides 5a opposed in the Y-axis direction in FIG. 2), and one other side 5a (one side 5a extending in the Y-axis direction in FIG. 2) which connects the above pair of the sides 5a are supported from the lower surface 5b by the support surface 11a of the substrate support section 11. In addition, the lower surfaces 5a of the three substrates 5 housed in each of the substrate housing holes 4A to 4C are supported by the rods 12A to 12C which extend in the Y-axis direction in FIG. 2 so as to pass through the vicinity of the centers of the substrates 5 in planar view.

After the three substrates 5 have been housed in each of the substrate housing holes 4A to 4C, the substrate housing holes 4A to 4C are not covered with the substrates 5 and penetrate from the upper surface 3a to the lower surface 3b in sections corresponding to the four chamfered corners of the substrates 5. Thus, a plurality of (eight in total in this embodiment) block plates 14 are mounted on the upper surface 3a of the tray 3 so as to cover the penetrating sections corresponding to the chamfered sections, and be configured and positioned so as not to interfere with the substrate 5.

Referring to FIG. 1, an antenna (plasma source) 17 serving as an upper electrode is arranged over a dielectric wall 18 which closes a top of the chamber 2 of the dry etching apparatus 1. The antenna 17 is electrically connected to a first high-frequency power supply 19A. Meanwhile, a stage 21 on which the tray 3 holding the substrates 5 is to be installed is arranged on a bottom side in the chamber 2. A process gas source 22 is connected to a gas inlet 2a of the chamber 2, and a decompression mechanism 23 including a vacuum pump for evacuating the chamber 11 is connected to an outlet 2b.

The stage 21 is arranged on a metal block 24, and the metal block 24 is housed in a base section 25. The metal block 24 is electrically connected to a second high-frequency power supply section 19B and functions as a lower electrode.

Referring to FIG. 2, the stage 21 has a rectangular shape in planar view, and includes a tray guide 26 having a rectangular frame shape in planar view, around an outer circumference of an upper surface 21a. The tray 3 is arranged in a region surrounded by the tray guide 26, in the upper surface 21a. An inner side surface of the tray guide 26 has an inclination fitted to the inclined surfaces 6a and 7a of the outer frames 6A to 7B of the tray 3, and functions as a tray guide surface 26a for guiding the tray 3.

Three raised substrate installation sections 27A, 27B, and 27C each having a roughly rectangular island shape in planar view are provided in the upper surface 21a of the stage 21 so as to correspond to the substrate housing holes 4 in the tray 3. A substantially horizontal upper end surface of each of the substrate installation sections 27A to 27C functions as a substrate installation surface 28 on which the three substrates 5 transferred from the corresponding one of the substrate housing holes 4A to 4C in the tray 3 (from the substrate support section 11, and the rods 12A to 12C) are installed. A height from the upper surface 21a of the stage 21 to the substrate installation surface 28 is set to be sufficiently greater than a height from the lower surface 3b of the tray 3 to the support surface 11a of the substrate support section 11. A side wall 29 of each of the substrate installation sections 27A to 27C has an inclination fitted to the inclined surface 11b of the substrate support section 11.

Three housing grooves 31A to 31C are provided in each of the substrate installation sections 27A to 27C to receive and house the rods 12A to 12C, respectively when the tray 3 is installed on the stage 21. The three housing grooves 31A to 31C extend in parallel to each other in the same direction (the Y-axis direction in FIG. 2). The three housing grooves 31A to 31C of the three substrate installation sections 27A to 27C are arranged on respective common lines (on lines in the y-axis direction in FIG. 2). Respective depths of the housing grooves 31A to 31C are set so that the rods 12A to 12C are housed in the housing grooves 31A to 31C without protruding from the substrate installation surface 28 when the tray 3 is installed on the stage 21.

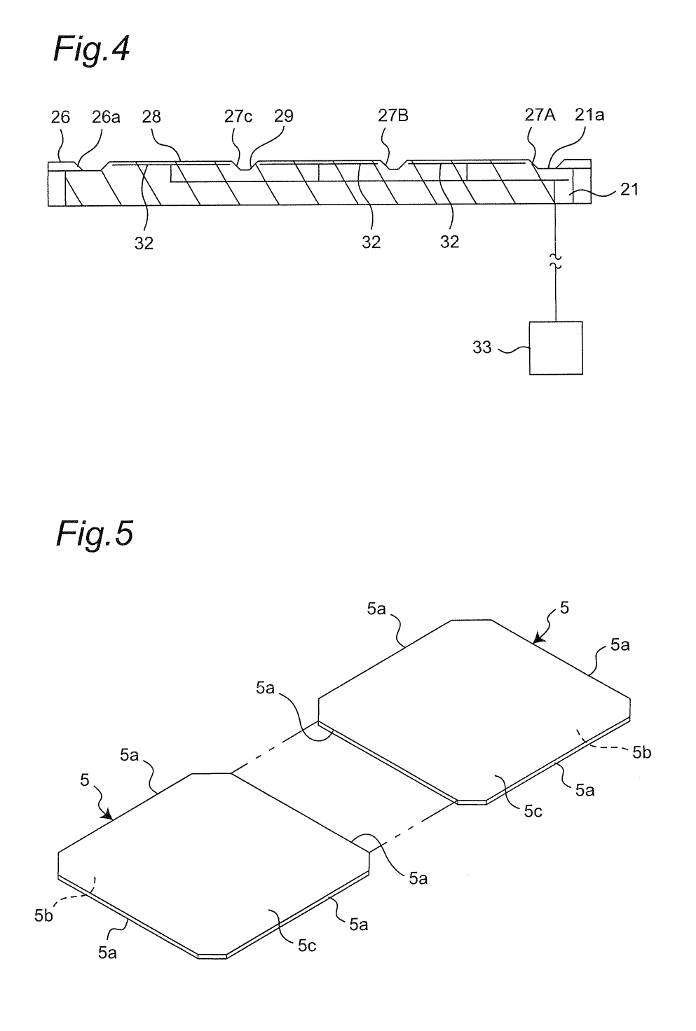

As conceptually shown in FIG. 4 only, the stage 21 includes an electrostatic chucking electrode 32 for electrostatically chucking the substrates 5, in the vicinity of the upper end surface (substrate installation surface 28) of each of the substrate installation sections 27A to 27C. A drive power supply 33 is electrically connected to the electrostatic chucking electrode 32. The electrostatic chucking electrode 32 may be a unipolar type or a bipolar type as long as the substrate 5 can be electrostatically chucked for sure onto the substrate installation surface 28. The electrostatic absorption electrode 32 may be provided on the surface of the stage 21 by spraying, for example.

Referring to FIG. 1, the dry etching apparatus 1 includes a cooling device 34 for the stage 21. The cooling device 34 includes a refrigerant flow path 35 formed in the metal block 24, and a refrigerant circulation device 36 for circulating a temperature-regulated refrigerant in the refrigerant path 35.

Referring to FIGS. 1 and 2, supply holes 37 for a heat-transfer gas are provided in the substrate installation surface 28 of each of the substrate installation sections 27A to 27C at positions corresponding to the three substrates 5 to be installed. These supply holes 37 are connected to a common heat-transfer gas source 38.

Lift pins 40 are provided in the chamber 2 in such a manner that they penetrate the base section 25, the metal block 24, and the stage 21, and are driven by a drive device 39 so as to be lifted up and down.

A controller 41 controls operations of the components of the dry etching apparatus 1, such as the first and second high-frequency power supplies 19A and 19B, the process gas source 22, the heat-transfer gas source 38, the decompression mechanism 23, the cooling device 34, the drive power supply 33, and the drive device 39.

Next, operations of the dry etching apparatus 1 in this embodiment will be described.

First, the three substrates 5 are housed in each of the three substrate housing holes 4A to 4C in the tray 1. The substrates 5 supported by the substrate support section 11 and the rods 12A to 12C in the tray 3 are exposed on the lower surface 3b of the tray 3 in the substrate housing holes 4A to 4C. The outer edge section of the lower surface 5b of the substrate 5 is supported by the support surface 11a of the substrate support section 11, and in addition, the center thereof is supported by the rods 12A to 12C. As a result, a deflection due to an own weight of the substrate 5 (which is noticeable in the vicinity of its center especially in planar view) can be surely prevented.

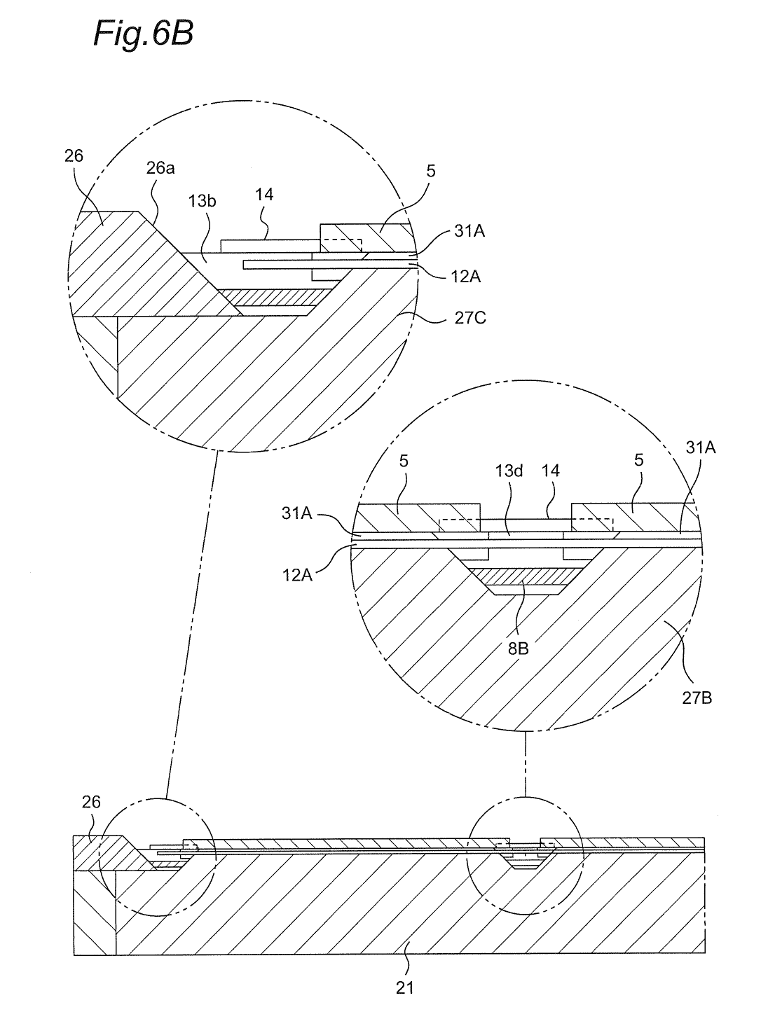

The tray 3 housing the substrates 5 is conveyed into the chamber 2, and received by the lift pins 40 whose tip ends project to a position sufficiently above the upper surface 21a of the stage 21. That is, as shown in FIGS. 6A and 7A, the tray 3 housing the substrates 5 is positioned above the upper surface 21a of the stage 21.

Then, the lift pins 40 are lowered, and the tray 3 is lowered toward the stage 21. The inclined surface 6a of each of the outer frames 6A to 7C is guided by the guide surface 26a of the tray guide 26 of the stage 21, so that the tray 3 is smoothly lowered while keeping an appropriate posture with respect to the stage 21. Referring to FIGS. 6B and 7B, the tray 3 is lowered until the inclined surface 11b on the lower side of the substrate support section 11 is installed on the side wall 29 (functioning as the tray support section in this embodiment) of each of the substrate installation sections 27A to 27C of the stage 21. That is, the tray 3 is lowered to the position so that it is supported by the stage 21. In addition, as another configuration, the lower surface 3b of the tray 3 may be installed on the upper surface 21a of the stage 21, and the upper surface 21a of the stage 21 may function as the tray support section.

While the tray 3 is lowered toward the stage 21, the substrate installation sections 27A to 27C of the stage 21 enter the corresponding substrate housing holes 4A to 4C in the tray 3 from the side of the lower surface 3b of the tray 3. While the tray 3 comes close to the stage 21, the substrate installation surfaces 28 as the tip ends of the substrate installation sections 27A to 27C enter the substrate housing holes 4A to 4C toward the upper surface 3a of the tray 3. In addition, the rods 12A to 12C in the tray 3 enter the housing grooves 31A to 31C, respectively in the substrate installation sections 27A to 27C.

As shown in FIGS. 6B and 7B, when the inclined surface 11b of the substrate support section 11 of the tray 3 is installed on the side wall 29 of each of the substrate installation sections 27A to 27C of the stage 21, the substrates 3 in each of the substrate housing holes 4A to 4A are lifted from the support surface 11a of the substrate support section 11 by each of the substrate installation sections 4A to 4C. More specifically, the lower surface 5b of the substrate 5 is installed on the substrate installation surface 28 of each of the substrate installation sections 4A to 4C, and arranged above the support surface 11a of the substrate support section 11 with a space. In short, the substrate 5 is transferred from the substrate support section 11 of the tray 3 to the substrate installation surface 28 of each of the substrate installation sections 27A to 27C.

Then, a DC voltage is applied from the drive power supply 33 to the electrostatic chucking electrode 32, and the three substrates 5 are electrostatically chucked onto the substrate installation surface 28 of each of the substrate installation sections 27A to 27C. Then, the heat-transfer gas is supplied from the heat-transfer gas source 38 through the supply holes 37. After that, the process gas is supplied from the process gas source 22 to the chamber 2, and a predetermined pressure is maintained in the chamber 2 by the decompression mechanism 23. Then, the high-frequency voltage is applied from the high-frequency power supply 19A to the antenna 17 to generate the plasma in the chamber 3, and a bias power is supplied from the high-frequency power supply 19B to the metal block 24 provided on the side of the stage 21. The substrates 2 are etched by the plasma.

During the etching, the metal block 24 is cooled by the refrigerant circulated in the refrigerant flow path 35 by the refrigerant circulation device 36, so that the substrates 5 held on the substrate installation surfaces 28 of the substrate installation sections 27A to 27C in the stage 21 are cooled. As described above, the lower surface 5b of the substrate 5 is directly installed on the substrate installation surface 28 without having the tray 3 between them, and held with a high degree of adhesion. Therefore, heat conductivity is high between the substrate 5 and the substrate installation surface 28 with the heat-transfer gas provided between them. As a result, the substrates 5 held on the substrate installation surface 28 of each of the substrate installation sections 27A to 27C can be cooled with a high degree of cooling efficiency, and a temperature of the substrate 2 can be controlled with high precision.

In addition, since the three substrates 5 can be housed in each of the three substrate housing holes 4A to 4C in the one tray 3, and the nine substrates 5 in total can be installed on the stage 21, a batch process can be performed and preferable productivity can be provided.

In addition, not one but three substrates 5 are housed in each of the substrate housing holes 4A to 4C in the tray 3, and the three substrates 5 transferred from the substrate support section 11 of each of the corresponding substrate housing holes 4A to 4C are installed on the substrate installation surface 28 of each of the substrate installation sections 27A to 27C in the stage 21. Since the plurality of the substrates 5 are housed in the substrate housing holes 4A to 4C in the tray 3, the tray 3 can be prevented from being increased in size, and therefore the dry etching apparatus can be prevented from being increased in size. Hereinafter, this point will be described. For example, in a case where the substrate housing hole capable of housing the one substrate 5 only is provided in the tray 3, the tray 3 needs to have frame sections for defining the nine substrate housing holes, so that the tray 3 is inevitably increased in size. In addition, when the tray 3 is increased in size, a width and a thickness of the frame section need to be increased to ensure strength and rigidity, so that its weight is also increased. Meanwhile, according to this embodiment, since the three substrate housing holes 4A to 4C each capable of housing the three substrates 5 are employed, the tray 3 has only the outer frames 6A to 7B and the two middle frames 8A and 8B to define the substrate housing holes 4A to 4C, so that the tray 3 can be prevented from being increased in size and weight.

Still furthermore, the configuration in which not the single substrate 5 but the three substrates 5 are housed in each of the substrate housing holes 4A to 4C in the tray 3 is preferable in view of yield. Hereinafter, this point will be described. For example, in the case where only the one substrate 5 is housed in each substrate housing hole in the tray 3, the nine substrate housing holes corresponding to the number of the substrates 5 are needed, and the tray 3 needs to have the frame sections for defining the nine substrate housing holes. In this configuration, each of the substrates 5 is etched so that its four sides 5a are all surrounded by the frame-shaped sections, so that a variation in etching is generated between a center section and a peripheral section in the substrate 5 due to a loading effect. Meanwhile, according to this embodiment, etching is performed so that the three substrates 5 abut on each other and are installed on the one substrate installation surface 28 like one substrate, so that a section which is affected by the loading effect, in each substrate 5 can be substantially reduced, which can contribute to improvement in yield.

Furthermore, since the configuration is provided such that the three substrates 5 are arranged on the substrate installation surface 28 of each of the substrate installation sections 27A to 27C, the structure of the stage 21 can be simplified, compared with the case where the one substrate installation section is provided for the one substrate.

The substrates 5 are housed in each of the substrate housing holes 4A to 4C in the tray 3 under the condition that their sides 5a serving as the abutment section abut on each other, and this condition is also maintained after they have been transferred to the substrate installation surface 28 of each of the substrate installation sections 27A to 27C in the stage 21. In this respect, an area of the group of the three substrates 5 is miniaturized in planar view. In this respect also, the tray 3 and the stage 21 can be prevented from being increased in size.

As described above, according to the plasma processing apparatus in the present invention, the high shape controllability and the favorable productivity can be both realized while the device is prevented from being increased in size.

When the substrate installation surface 28 has a section which causes a change in structure or material quality, a bias execution power is changed in that section, so that etching uniformity is affected, which is not preferable. In view of this, each of the housing grooves 31A to 31C formed in the substrate installation surface 28 in each of the substrate installation sections 27A to 27C is preferably small in width and shallow in depth. That is, when each of the housing grooves 31A to 31C is small in width and shallow in depth, the change in bias execution power is minimized, and the etching uniformity can be ensured. Therefore, each of the rods 12A to 12C housed in the housing grooves 31A to 31C is preferably as thin as possible to the extent that the rigidity can be ensured to prevent the deflection from being generated in the center of each of the substrates 5 housed in the substrate housing holes 4A to 4C. For example, when each of the rods 12A to 12C is circular in cross-section like in this embodiment, a diameter of each of the rods 12A to 12C is preferably as small as possible to the extent that the rigidity capable of supporting the substrate 5 can be ensured.

The present invention is not limited to the above embodiment, and various modifications can be made.

According to the embodiment, the three substrates 5 are housed in each of the substrate housing holes 4A to 4C in the tray 3, and the three substrates 5 are installed on the substrate installation surface 28 of each of the substrate installation sections 27A to 27C. However, the number of the substrates housed in the substrate housing hole in the tray, that is, the number of the substrates installed on the substrate installation surface of the substrate installation section may be two, four, or more.

The deflection prevention member of the substrate 5 is not limited to the rods 12A to 12C in the embodiment. Its number and shape are not limited as long as the substrate 5 housed in each of the substrate housing holes 4A to 4C is surely prevented from being deflected due to its own weight while the substrate 5 is not prevented from being installed on the substrate installation surface 28 of each of the substrate installation sections 27A to 27C. For example, as another configuration, the three same rods as the embodiment may be provided with respect to each substrate 5. In a case where the substrate 5 is thick and its deflection due to its own weight is small or hardly generated, there is no need to provide the deflection prevention member such as the rod. When the deflection prevention member is not provided, there is no need to provide the retention grooves 13a to 13d in the tray 3, and there is no need to provide the housing grooves 31A to 31C in the substrate installation sections 27A to 27C, so that the device configuration can be more simplified.

The shape of the substrate is not limited to the angular substrate as long as there is an abutment section, and the plurality of the substrates can be housed in the substrate housing hole in the tray.

While the present invention has been described, taking the ICP type dry etching processing device as one example, the present invention can be applied to a RIE (reactive ion) type dry etching apparatus, a plasma processing apparatus for plasma CVD, and a plasma processing method.

### REFERENCE SIGNS LIST

1 Dry etching apparatus
2 Chamber
2a Gas inlet
2b Outlet
3 Tray
3a Upper surface
3b Lower surface
4A, 4B, 4C Substrate housing hole
5 Substrate
5a Side
5b Lower surface
5c Upper surface
6A, 6B, 7A, 7B Outer frame
6a, 7a Inclined surface
8A, 8B Middle frame
11 Substrate support section
11a Support surface
11b Inclined surface
12A, 12B, 12C Rod
13a, 13b, 13c, 13d Retention groove
14 Block plate
17 Antenna
18 Dielectric wall
19A, 19B High-frequency power supply
21 Stage
21a Upper surface
22 Process gas source
23 Decompression mechanism
24 Metal block
25 Base section
26 Tray guide
26a Tray guide surface
27A, 27B, 27C Substrate installation section
28 Substrate installation surface
29 Side wall
31A, 31B, 31C Housing groove
32 Electrostatic chucking electrode
33 Drive power source
34 Cooling device
35 Refrigerant flow path
36 Refrigerant circulation device
37 Supply hole
38 Heat-transfer gas source
39 Drive device
40 Lift pin
41 Controller

1. A plasma processing apparatus comprising:
a conveyable tray comprising at least one substrate housing hole provided so as to penetrate in a thickness direction to house a plurality of substrates, and a substrate support section protruding from a hole wall of the substrate housing hole to support an outer edge section of a lower surface of each of the plurality of the substrates housed in the substrate housing hole;
a plasma generation source for generating plasma in a chamber in which the tray is to be conveyed; and
a stage arranged in the chamber and comprising a tray support section for supporting the tray, and a substrate installation section to be inserted from a lower surface side of the tray to the substrate housing hole, to install lower surfaces of the plurality of the substrates transferred from the substrate support section on a substrate installation surface which is an upper end surface of the substrate installation section.

2. The plasma processing apparatus according to claim 1, wherein the tray houses the plurality of the substrates so that abutment sections of the adjacent substrates abut on each other.

3. The plasma processing apparatus according to claim 2, wherein the substrate is an angular substrate, and the abutment section is one side of the angular substrate.

4. The plasma processing apparatus according to claim 1, further comprising:
a deflection prevention member provided in the tray so as to cross the substrate housing hole in planar view to support a lower surface side of the substrate; and
a housing groove provided in the substrate support section of the stage to receive the deflection prevention member when the tray is supported by the tray support section.

5. The plasma processing apparatus according to claim 1, further comprising:
an electrostatic chucking electrode for electrostatically chucking the substrate onto the substrate installation surface; and
a drive power supply for supplying a drive voltage to the electrostatic chucking electrode.

6. The plasma processing apparatus according to claim 5, further comprising a cooling mechanism for cooling the stage.

7. The plasma processing apparatus according to claim 6, further comprising a heat-transfer gas supply mechanism for supplying a heat-transfer gas between the substrate installation surface and the substrate.

8. A plasma processing method comprising:
providing a tray having at least one substrate housing hole provided so as to penetrate in a thickness direction to house a plurality of substrates, and a substrate support section protruding from a hole wall of the substrate housing hole;
housing the plurality of the substrates in the substrate housing hole in the tray so that an outer edge section of a lower surface of each of the substrates is put on the substrate support section;
lowering the tray toward a stage in a chamber so that the tray is supported with a tray support section of the stage while a substrate installation section is inserted from a lower surface side of the tray into the substrate housing hole, thereby installing the lower surfaces of the plurality of the substrates housed in the substrate housing hole, on a substrate installation surface which is an upper end surface of the substrate installation section, and
generating plasma in the chamber.

9. The plasma processing method according to claim 8, wherein the plurality of the substrates are housed in the substrate housing hole in the tray in such a manner that abutment sections of the adjacent substrates abut on each other.

10. The plasma processing method according to claim 9, wherein the substrate is an angular substrate, and the abutment section is one side of the angular substrate.
